(19) United States
(12) Patent Application Publication
(10) Pub. No.: US 2007/0258282 A1
(43) Pub. Date: Nov. 8, 2007

(54) MAGNETIC MEMORY DEVICE AND METHOD OF WRITING DATA IN THE SAME

(76) Inventors: Yoshihiro UEDA, Yokohama-shi (JP); Tsuneo Inaba, Kamakura-shi (JP); Yuui Shimizu, Yokohama-shi (JP); Kiyotaro Itagaki, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/682,934

(22) Filed: Mar. 7, 2007

(30) Foreign Application Priority Data
Apr. 12, 2006 (JP) 2006-109926

(51) Int. Cl. G11C 11/00

(52) U.S. Cl. 365/158

(57) ABSTRACT

A magnetic memory device includes a magnetoresistance element which has first and second ends. First data is written into the magnetoresistance element by an electric current flowing from the first end to the second end. Second data is written into the magnetoresistance element by an electric current flowing from the second end to the first end. A first p-type MOSFET has one end connected to the first end. A second p-type MOSFET has one end connected to the second end. A first n-type MOSFET has one end connected to the first end. A second n-type MOSFET has one end connected to the second end. A current source circuit is connected to each another end of the first and second p-type MOSFETs and supplies an electric current. A current sink circuit is connected to each another end of the first and second n-type MOSFETs and draws an electric current.

### CROSS-REFERENCE TO RELATED APPLICATIONS

This application is based upon and claims the benefit of priority from prior Japanese Patent Application No. 2006-109926, filed Apr. 12, 2006, the entire contents of which are incorporated herein by reference.

### BACKGROUND OF THE INVENTION

1. Field of the Invention

The present invention relates to a magnetic memory device, and relates, for example, to a spin injection write type magnetic memory device.

2. Description of the Related Art

A magnetoresistance element is known as one of resistance-variance type nonvolatile memory devices. The magnetoresistance element includes a free layer and a pinned layer, which are magnetic layers, and a non-magnetic layer which is interposed between the free layer and pinned layer. The resistance state of the magnetoresistance element varies in accordance with the direction of magnetization of the free layer. A magnetic random access memory (MRAM) is a magnetic memory device which makes use of such a change in resistance state in order to store information.

Information read-out is effected by letting an electric current flow through the magnetoresistance element, converting the resistance value to a current value or a voltage value, and comparing the current value or voltage value with a reference value. Information write is effected by reversing the direction of magnetization in the free layer by a magnetic field that is generated by an electric current flowing through two mutually perpendicular write lines in the memory cell.

Development in shrinkage of magnetic memory devices reduces the size of the write line and magnetoresistance element and the distances between various components. As a result, a magnetic field generated from the write line in which a write current flows may cause unintended writing on a non-target memory cell near the write line. This tendency becomes more conspicuous with development in shrinkage of magnetic memory devices.

In addition, smaller magnetoresistance element requires a larger magnetic field necessary for a write operation. Generating a sufficiently great magnetic field demand a higher write current. This makes it difficult to reduce power consumption of the magnetic memory device.

Aside from the magnetic field write type magnetic memory device, a so-called spin injection write type magnetic memory device has been proposed (U.S. Pat. No. 5,695,864). The spin injection write method involves providing the free layer of the magnetoresistance element with a flow of electrons which are spin-polarized by magnetic moment of the fixed layer. The direction of magnetization of the free layer is varied in accordance with the direction of the electron flow and thereby specific data is written in the magnetoresistance element. The spin injection write method can pose direct influence on the element compared to the magnetic field write method. Thus, unintended write in a neighboring memory cell can be prevented. Moreover, there is an advantage that a current amount necessary for a write operation decreases in accordance with reduction in cell size.

The spin injection write method requires an electric current to flow in two directions, specifically from one end to the other end of the magnetoresistance element and vice versa, in accordance with write data. Thus, the magnetic memory device is required to have such a structure as to realize such current supply. Since the magnetic field write method does not demand this structure, it is not possible to apply the structure for the magnetic field write method to the spin injection write method. There is a demand for a structure that is suited to the spin injection write method.

### BRIEF SUMMARY OF THE INVENTION

A magnetic memory device comprising: a first magnetoresistance element having a first end and a second end, first data being written into the first magnetoresistance element by an electric current flowing from the first end to the second end, and second data being written into the first magnetoresistance element by an electric current flowing from the second end to the first end; a first p-type MOSFET having one end connected to the first end; a second p-type MOSFET having one end connected to the second end; a first n-type MOSFET having one end connected to the first end; a second n-type MOSFET having one end connected to the second end; a first current source circuit connected to another end of the first p-type MOSFET and another end of the second p-type MOSFET and supplying an electric current; and a first current sink circuit connected to another end of the first n-type MOSFET and another end of the second n-type MOSFET and drawing an electric current.

### BRIEF DESCRIPTION OF THE SEVERAL VIEWS OF THE DRAWING

FIG. 1 shows generally conceivable circuit diagram of a magnetic memory device for general spin injection method;

FIG. 2 shows a circuit diagram of a magnetic memory device according to a first embodiment of the invention;

FIG. 3 shows a side view of a magnetoresistance element;

FIG. 4 shows a control circuit of the magnetic memory device;

FIG. 5 and FIG. 6 show write states of the magnetic memory device;

FIG. 7 shows a modification of the first embodiment;

FIG. 8 shows a circuit diagram of a magnetic memory device according to a second embodiment of the invention;

FIG. 9 shows a circuit diagram of a magnetic memory device according to a third embodiment of the invention;

FIG. 10 shows a circuit diagram of a magnetic memory device according to a fourth embodiment of the invention;

FIG. 11 shows a circuit diagram of a magnetic memory device according to a fifth embodiment of the invention; and

FIG. 12 shows a modification of the first embodiment.

### DETAILED DESCRIPTION OF THE INVENTION

In the course of the development of the present invention, the inventors studied a magnetic memory device which is suited to a spin injection write method. As a result, the inventors obtained the following finding.

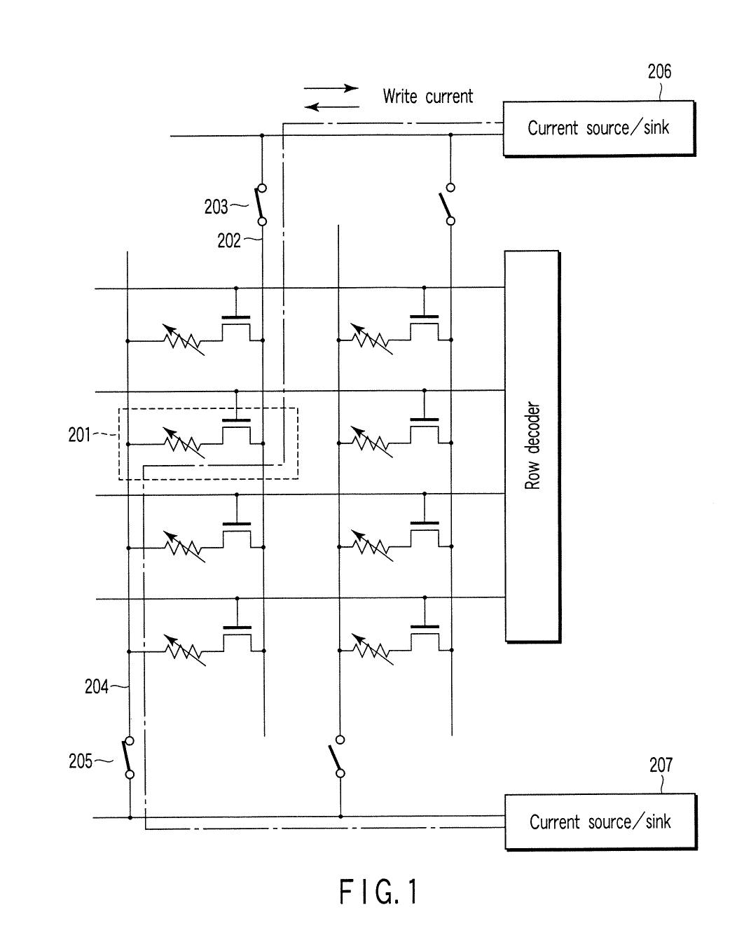

The spin injection write method requires a structure that allows currents to flow through the magnetoresistance element in two directions in accordance with write data as described above. If this structure is to be realized with no particular consideration to other design factors, a structure as shown in FIG. 1 may generally be conceivable.

As is shown in FIG. 1, memory cells 201, each comprising a magnetoresistance element and a select transistor which are connected in series, are provided. One end (e.g. right end) of each of the memory cells 201 in the same column (or row) is connected to an associated one of connection lines 202. Each of the connection lines 202 is connected to a current source/sink circuit 206 via a switch circuit 203 such as a transistor.

Similarly, the other end (e.g. left end) of each of the memory cells 201 in the same column (or row) is connected to an associated one of connection lines 204. Each of the connection lines 204 is connected to a current source/sink circuit 207 via a switch circuit 205 such as a transistor.

The current source/sink circuit 206, 207 can supply an electric current to the associated connection lines 202, 204, and draw an electric current from the connection lines 202, 204.

When information is to be written in a certain memory cell 201, the select transistor of this memory cell 201 is turned on and the switch circuits 203 and 205, which are connected to the access lines 202 and 204 of the memory cell column including this memory cell 201, are turned on. One of the current source/sink circuits 206 and 207 functions as a current source circuit, and the other functions as a current sink circuit in accordance with write data. As a result, as shown in FIG. 1, a write current flows between the source/sink circuits 206 and 207 via the switch circuit 203, connection line 202, memory cell 201, connection line 204 and switch circuit 205.

This structure uses the same path of the write current regardless of the write data for each magnetoresistance element, and the switch circuit 203, 205 is possible to be connected to both the current source circuit and current sink circuit, depending on the write data. Thus, a so-called “threshold drop” occurs and the following problem arises. The threshold drop refers to a voltage drop which is substantially equivalent to a threshold voltage and occurs between both ends of a metal oxide semiconductor field effect transistor (MOSFET) due to the conductivity type and potential applied on the MOSFET.

For example, consider the case in which an n-type MOSFET (also referred to simply as “transistor”) is turned on by applying a potential Vdd to the gate electrode of the transistor with a potential Vdd applied to its drain. This transistor is turned on when the following condition is satisfied:

Vgs=Vg−Vs=Vdd−Vs>Vth

where Vgs is a gate-source voltage (gate potential Vg−source potential Vs), and Vth is a threshold voltage of the transistor.

The source potential Vs is expressed by

Vs<Vdd−Vth

and is less than Vdd.

If the switches 203 and 205 are each realized by the n-MOSFET, the potential at the connection node between the transistors 203 and 205, each of which is connected to the current source circuit, and the memory cell is equal to power supply voltage Vdd−the threshold voltage of transistor 203 (or 205). As a result, smaller voltage is applied to the memory cell, which causes diminished current to flow through the memory cell.

The same holds true when each switch circuit 203, 205 is realized by a p-MOSFET, instead of the n-MOSFET. Specifically, the potential at the connection node between the switch circuits 203 and 205, which is connected to the current sink circuit, and the memory cell is an absolute value of (ground potential Vss+threshold voltage of transistor 203 (or 205)), which also decrease the write current flowing to the memory cell.

It is thinkable that one of the switch circuits 203 and 205 is realized by a p-MOSFET and the other is realized by an n-MOSFET. This approach forms the same current path from the current source circuit to the current sink circuit via the selected memory cell regardless of write data with respect to each selected memory cell. As a result, two states may occur, that is, a state (first state) in which the p-MOSFET is connected to the current source circuit and the n-MOSFET is connected to the current sink circuit, and a state (second state) in which the p-MOSFET is connected to the current sink circuit and the n-MOSFET is connected to the current source circuit.

In the first state, one end of the p-MOSFET is connected to the power supply potential Vdd and one end of the n-MOSFET is connected to the ground potential Vss. Thus, no threshold drop occurs in either of the MOSFETs. In the second state, however, one end of the p-MOSFET is connected to the ground potential and one end of the n-MOSFET is connected to the power supply potential. Thus, a threshold drop occurs in both MOSFETs to considerably decrease the voltage applied to the memory cell. Hence, this approach cannot be adopted.

Embodiments of the present invention, which are constructed on the basis of the above finding, will now be described with reference to the accompanying drawings. In the description below, the structural elements having substantially the same functions and structures are denoted by like reference numerals, and an overlapping description is given only where necessary.

### First Embodiment

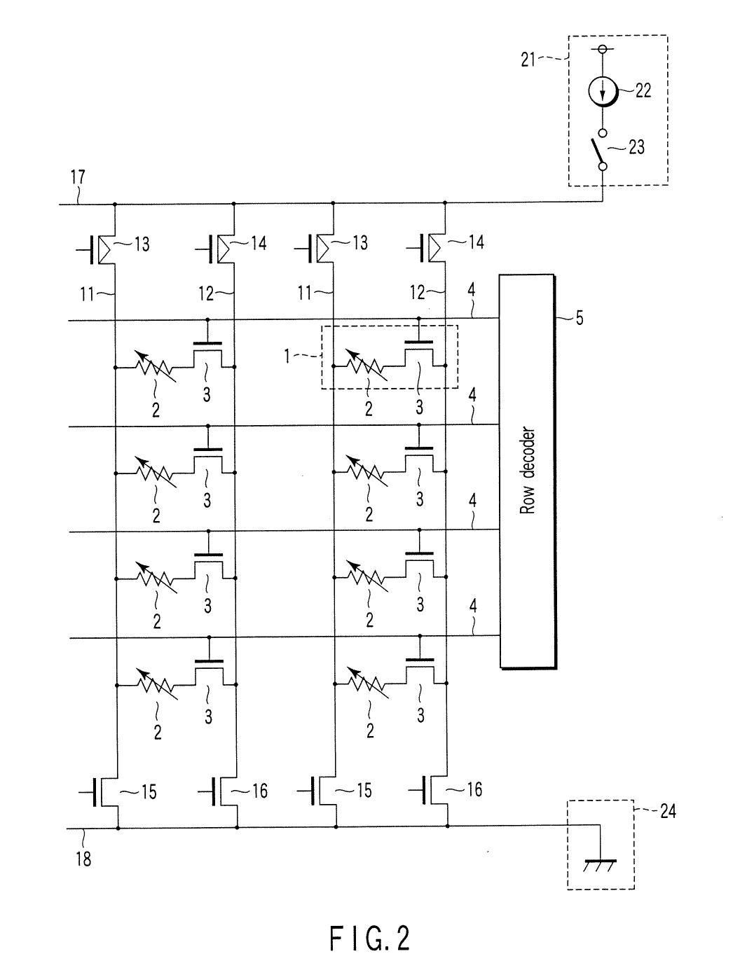

FIG. 2 shows a circuit structure of a magnetic memory device (MRAM) according to a first embodiment of the invention. As shown in FIG. 2, memory cells 1 are arrayed in a matrix. Each memory cell 1 comprises a magnetoresistance element 2 and a select transistor 3 which are connected in series.

The magnetoresistance element 2 is configured to take one of two stable states when a current of spin-polarized electrons (i.e. spin-polarized current) is supplied from one to the other of the two ends of the magnetoresistance element 2, or vice versa. The respective stable states are associated with “0” data and ∫1” data, and thereby the magnetoresistance element 2 can store two-value data.

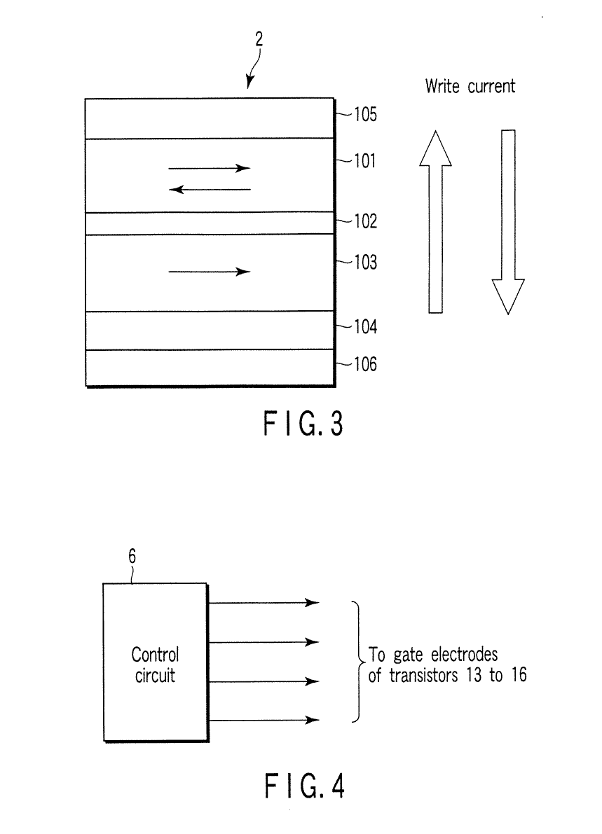

A most typical example of the magnetoresistance element 2 is shown in FIG. 3. As shown in FIG. 3, the magnetoresistance element 2 includes, at least, a pinned layer 103 of ferromagnetic material, an intermediate layer 102 of non-magnetic material, and a free layer (recording layer) 101 of ferromagnetic material, which are stacked in the mentioned order.

The free layer 101 and/or the pinned layer 103 may be formed to have a stacked structure of sub-layers. The magnetization direction of the pinned layer 103 is fixed. This is realized, for example, by providing an antiferromagnetic layer 104 on that surface of the pinned layer 103, which is opposed to the non-magnetic layer.

On the other hand, with respect to the magnetization direction of the free layer 101, such a fixing mechanism is not provided. Thus, the magnetization direction of the free layer 101 varies.

The intermediate layer 102 is formed of, e.g. a non-magnetic metal, a non-magnetic semiconductor, or an insulating film.

Electrodes 105 and 106 may be provided on that surface of the free layer 101, which is opposed to the non-magnetic layer 102, and on that surface of the antiferromagnetic layer 104, which is opposed to the pinned layer 103.

An electron current is let to flow from the pinned layer 103 to the free layer 101 in order to reverse the magnetization direction of the free layer 101 which is antiparallel to the magnetization direction of the pinned layer 103 and to make it parallel to the magnetization direction of the pinned layer 103. In general, a major part of an electron current flowing through a magnetic body has a spin which is parallel to the magnetization direction of the magnetic body. Accordingly, the major part of the electron current flowing through the pinned layer 103 has a spin parallel to the magnetization direction of the pinned layer 103. This major part of the electron current mainly contributes to a torque acting on the magnetization of the free layer 101. The other part of the electron current has a spin which is antiparallel to the magnetization direction of the pinned layer 103.

Conversely, an electron current is let to flow from the free layer 101 to the pinned layer 103 in order to reverse the magnetization direction of the free layer 101 which is parallel to the magnetization direction of the pinned layer 103 and to make it antiparallel to the magnetization direction of the pinned layer 103. This electron current passes through the free layer 101, and a major part of the electron current, which has a spin that is antiparallel to the magnetization direction of the pinned layer 103, is reflected by the pinned layer 103 and returns to the free layer 101. The electrons which reenter the free layer 101 and have spins antiparallel to the magnetization direction of the pinned layer 103 mainly contribute to a torque acting on the magnetization of the free layer 101. A part, although small, of the electrons, which have passed through the free layer 101 and have spins antiparallel to the magnetization direction of the pinned layer 103, passes through the pinned layer 103.

For example, Co, Fe, Ni or an alloy including them can be used as the ferromagnetic material of the free layer 101 and pinned layer 103. For example, Fe—Mn, Pt—Mn, Pt—Cr—Mn, Ni—Mn, Pd—Mn, NiO, Fe₂O₃ or a magnetic semiconductor can be used as the material of the antiferromagnetic layer 104.

When a non-magnetic metal is used as the intermediate layer 102, it is possible to use one selected from the group consisting of Au, Cu, Cr, Zn, Ga, Nb, Mo, Ru, Pd, Ag, Hf, TA, W, Pt and Bi, or an alloy including at least one of these elements. When the intermediate layer 102 is made to function as a tunnel barrier layer, it is possible to use Al₂O₃, SiO₂, MaO, AlN, etc.

As shown in FIG. 2, the gate electrodes of the select transistors 3 in the same row are connected to the same one of select lines 4. The select lines 4 are connected to a row decoder 5. When write or read is executed, an address signal is supplied to the row decoder 5, and the select line 4 which is connected to the memory cell 1 at the address specified by the address signal is activated.

The memory cells in the same column are connected to the same one of connection lines 11 on the magnetoresistance element side, and connected to the same one of connection lines 12 on the select transistor side. One end of the connection line 11, 12 is connected to one end of a p-type MOSFET 13, 14, respectively. The other end of the connection line 11, 12 is connected to one end of an n-type MOSFET 15, 16, respectively.

The other end of the transistor 13, 14 is connected to a common line 17. The other end of the transistor 15, 16 is connected to a common line 18.

The common line 17 is connected to a current source circuit 21. The current source circuit 21 supplies a write current to the common line 17 at the time of write. The current source circuit 21 is, for example, composed of a constant current source 22 and a switch circuit 23 such as a transistor. The constant current source 22 and the switch circuit 23 are connected in series. An end of the switch circuit 23 which is opposed to the constant current source 21 is connected to the common line 17.

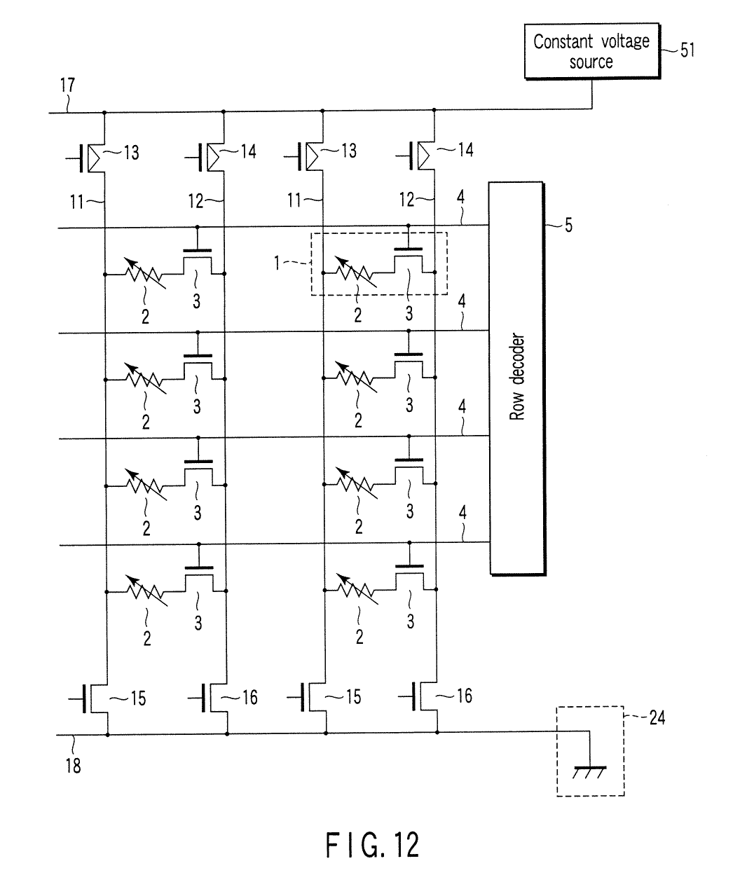

As is shown in FIG. 12, the common line 17 may be connected to a constant voltage source 51 which generates a write power supply potential Vwrite, instead of the current source 21. According to this structure, the common line 17 keeps precharged at a potential Vwrite to eliminate the need of recharge the common line 17 to the potential Vwrite at a write time, or to discharge the common line 17 after charging. This can realize a high-speed operation.

Referring back to FIG. 2, the common line 18 is connected to a current sink circuit 24. The current sink circuit 24 draws a write current from the common line 18 at the time of write. The current sink circuit 24 is, for example, configured to connect the common line 18 to a ground (common potential node).

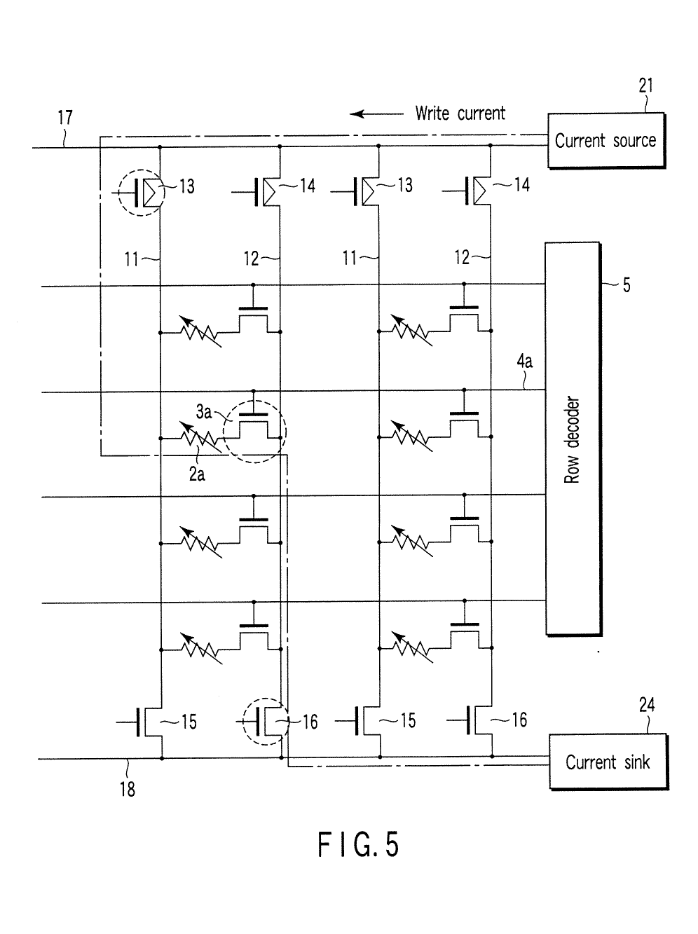

The gate electrodes of the transistors 13 to 16 are, as shown in FIG. 4, connected to a control circuit 6. The control circuit 6 controls on/off of the transistors 13 to 16 in accordance with an address signal which is supplied from outside.

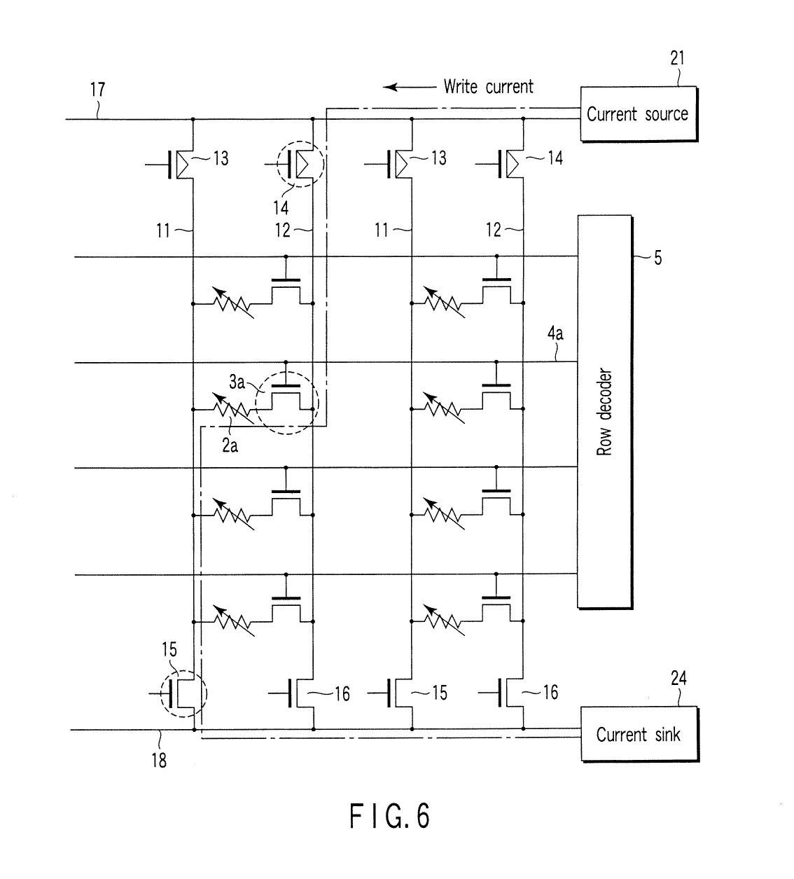

Next, the operation of the magnetic memory device shown in FIG. 2 is described with reference to FIG. 5 and FIG. 6. FIG. 5 and FIG. 6 show states in which mutually different data are written. FIG. 5 illustrates a case in which a write current flows from the magnetoresistance element 2 shown in FIG. 2 to the select transistor 3 (e.g. write of “0” data). FIG. 6 shows a case in which a write current flows from the select transistor 3 shown in FIG. 2 to the magnetoresistance element 2 (e.g. write of “1” data). In FIG. 5 and FIG. 6, turned-on transistors are circled by broken lines. During a standby state, as shown in FIG. 2, the select transistors 3 and transistors 13 to 16 are off.

As shown in FIG. 5, when a select line 4a which is connected to the gate electrode of a select transistor 3a of a write target memory cell 1 (selected memory cell) is activated, the select transistor 3a is turned on. Subsequently, transistors 13 and 16 in the column including the selected memory cell 1 are turned on. Transistors 14 and 15 stay off. The transistors 13 to 16 in the columns other than the column including the selected memory cell stay off.

In this state, the current source circuit 21 and current sink circuit 24 are activated. Specifically, the transistor 23 in the current source circuit 21 is turned on. As a result, a current path is formed between the current source circuit 21 to the current sink circuit 24 via the selected memory cell 1 and a write current flows through it. The write current flows through a magnetoresistance element (selected magnetoresistance element) 2a of the selected memory cell 1 in a first direction (i.e. a direction from the magnetoresistance element 2 towards the select transistor 3), and one (e.g. “0” data) of two data, which can be stored in the memory cell 1, is written.

Similarly, as shown in FIG. 6, the select transistor 3a of the selected memory cell 1 is turned on, and transistors 14 and 15 in the column including the selected memory cell 1 are turned on. Transistors 13 and 16 stay off. The transistors 13 to 16 in the columns other than the column including the selected memory cell stay off. In this state, the current source circuit 21 and current sink circuit 24 are activated. Thereby, a write current flows through the magnetoresistance element 2a in a second direction reverse to the first direction (i.e. a direction from the select transistor 3 toward the magnetoresistance element 2). As a result, the other (e.g. “1” data) of the two data, which can be stored in the memory cell 1, is written.

The aforementioned structure and write operation can provide write current paths dedicated for the respective data write operations. Thus, the source electrodes of the p-type MOSFETs 13 and 14 are always connected to the current source circuit 21, and the source electrodes of the n-type MOSFETs 15 and 16 are always connected to the current sink circuit 24 regardless of write data. Accordingly, no threshold drop occurs.

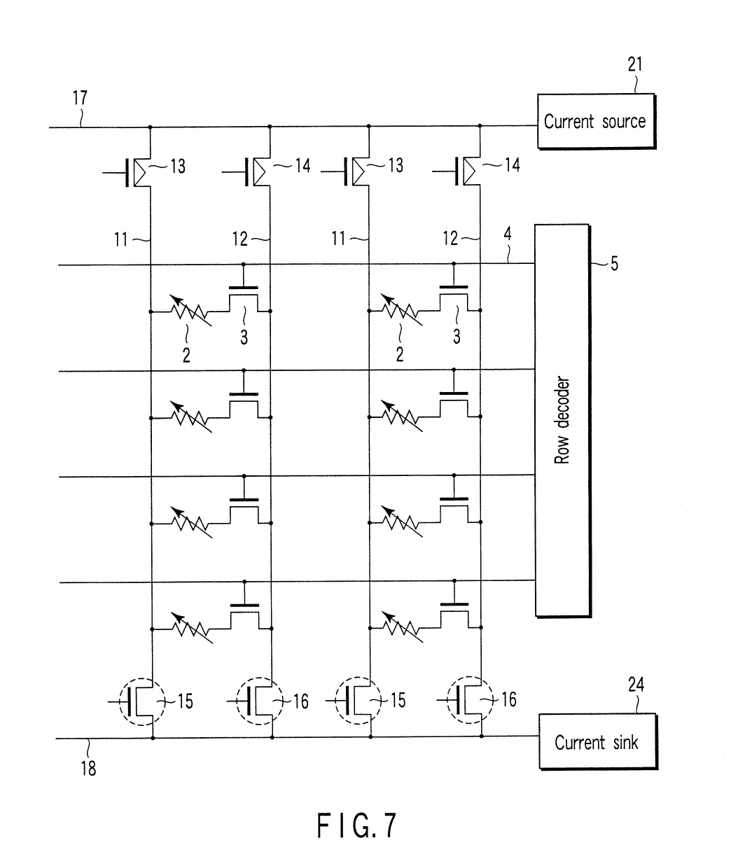

Next, with reference to FIG. 7, a modification of the control of the transistors 13 to 16 is described. FIG. 7 shows a modification of the first embodiment and illustrates a standby state. As shown in FIG. 7, during the standby state, all the transistors 13 and 14 are kept off, as in the case in FIG. 2. On the other hand, all the transistors 15 and 16 are kept on. This connection can keep both ends of each memory cell 1 at a ground potential after the write and read. This connection can keep the start point of the potential in each memory cell 1 at the write operation stable.

At the write time, as in the state of FIG. 5 or FIG. 6, the transistor 15 or transistor 16 in the column including the selected memory cell is kept on, while the other transistors 15 and 16 are turned off.

As has been described above, the magnetic memory device of the first embodiment of the invention causes no threshold drop. Therefore, it is possible to prevent the voltage applied to the memory cell 1 from lowering by the value corresponding to the threshold voltage of the transistors 13 to 16 from the applied voltage to the memory cell 1 without threshold drop.

The first embodiment, as described above, provides the dedicated write current paths for writing data, which can avoid the lowered application voltage to the memory cell 1 due to the threshold drop. As a result, it is possible to realize the magnetic memory device which has a large operation margin, and can efficiently supply write current to the memory cell.

Jpn. Pat. Appln. KOKAI Publication No. 2004-325100 discloses a structure where the connection node of serially-connected transistors Q1 and Q3 is connected to one end of a coil L1, and the connection node of serially-connected transistors Q2 and Q4 is connected to the other end of the coil L1, whereby two-directional current can be supplied to the coil L1.

This prior art discloses the structure that can flow a current to flow in two directions but all the transistors Q1 to Q4 are MOSFETs of the same conductivity type (n type). This point sharply makes the prior art different from the first embodiment of the invention which employs p-type MOSFETs and n-type MOSFETs in combination to avoid the voltage drop due to the threshold drop.

### Second Embodiment

A second embodiment of the invention relates to a structure where two neighboring memory cell arrays share a current source circuit.

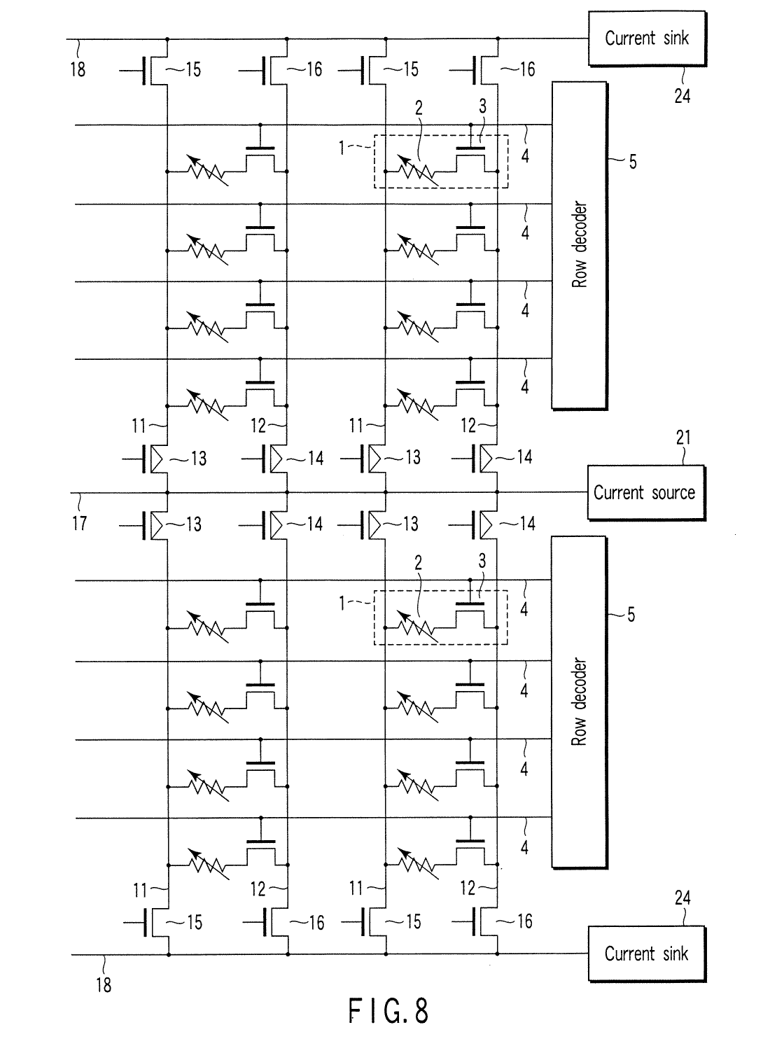

FIG. 8 shows a circuit configuration of a magnetic memory device according to the second embodiment of the invention. As shown in FIG. 8, a single common line 17 is provided with two units each of which comprises an array of memory cells 1 placed in a matrix, select lines 4, a row decoder 5, connection lines 11 and 12, transistors 13 to 16, a common line 18 and a current sink circuit 24. The common line 17 is further connected to a current source circuit 21.

During a standby state, all the transistors 13 to 16 stay off. At the time of write, both transistors 13 and 16 or both transistors 14 and 15 in the column including the selected memory cell 1 are turned on, as shown in FIG. 5 or FIG. 6. The other transistors 13 to 16 stay off.

During the standby state, the transistors 15 and 16 may stay on as in the case shown in FIG. 7, which can fix both ends of the memory cells 1 at the ground potential. When this technique is employed, one of the transistors 15 and 16 in the column including the selected memory cell 1 and the transistors 15 and 16 in the columns other than the column including the selected memory cell are turned off at the write time as described in connection with FIG. 7.

The magnetic memory device of the second embodiment of the invention provides dedicated write current paths for each polarity of write data, like the first embodiment. Thus, the sources of the p-type MOSFETs 13 and 14 are connected to the current source circuit 21 and the sources of the n-type MOSFETs 15 and 16 are connected to the current sink circuit 24 regardless of write data. Therefore, no threshold drop occurs, and the same advantageous effect as in the first embodiment is obtained.

Further, according to the second embodiment, the two memory cell arrays share the single current source circuit 21. Thus, the plan-view area of the magnetic memory device can be smaller than the configuration where a current source circuit 21 and a current sink circuit 24, which are paired, are provided for each memory cell array.

### Third Embodiment

A third embodiment of the invention relates to a structure where two neighboring memory cell arrays share a current sink circuit.

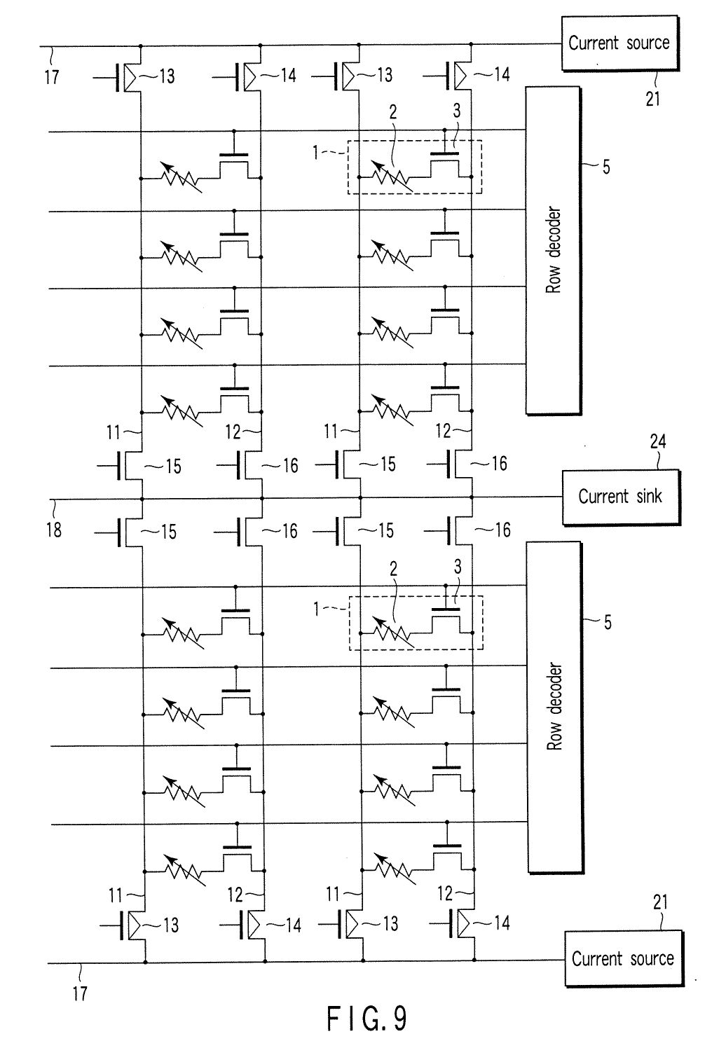

FIG. 9 shows a circuit configuration of a magnetic memory device according to the third embodiment of the invention. As shown in FIG. 9, a single common line 18 is provided with two units each of which comprises an array of memory cells 1 placed in a matrix, select lines 4, a row decoder 5, connection lines 11 and 12, transistors 13 to 16, a common line 17 and a current source circuit 21. The common line 18 is further connected to a current sink circuit 24.

During a standby state, all the transistors 13 to 16 stay off. At the time of write, both transistors 13 and 16 or both transistors 14 and 15 in the column including the selected memory cell 1 are turned on, as shown in FIG. 5 or FIG. 6. The other transistors 13 to 16 stay off.

During the standby state, the transistors 15 and 16 may stay on as in the case shown in FIG. 7, which can fix both ends of the memory cells 1 at the ground potential. When this technique is employed, one of the transistors 15 and 16 in the column including the selected memory cell 1 and the transistors 15 and 16 in the columns other than the column including the selected memory cell are turned off at the write time as described in connection with FIG. 7.

The magnetic memory device of the third embodiment of the invention provides dedicated write current paths which are provided for each polarity of write data, like the first embodiment. Thus, the sources of the p-type MOSFETs 13 and 14 are connected to the current source circuit 21 and the sources of the n-type MOSFETs 15 and 16 are connected to the current sink circuit 24 regardless of write data. Therefore, no threshold drop occurs, and the same advantageous effect as in the first embodiment is obtained.

Further, according to the third embodiment, the two memory cell arrays share the single current sink circuit 24. Thus, the plan-view area of the magnetic memory device can be smaller than the configuration where a current source circuit 21 and a current sink circuit 24, which are paired, are provided for each memory cell array.

### Fourth Embodiment

A fourth embodiment of the invention relates to a structure (control circuit 6) for controlling on/off of the transistors 13 to 16.

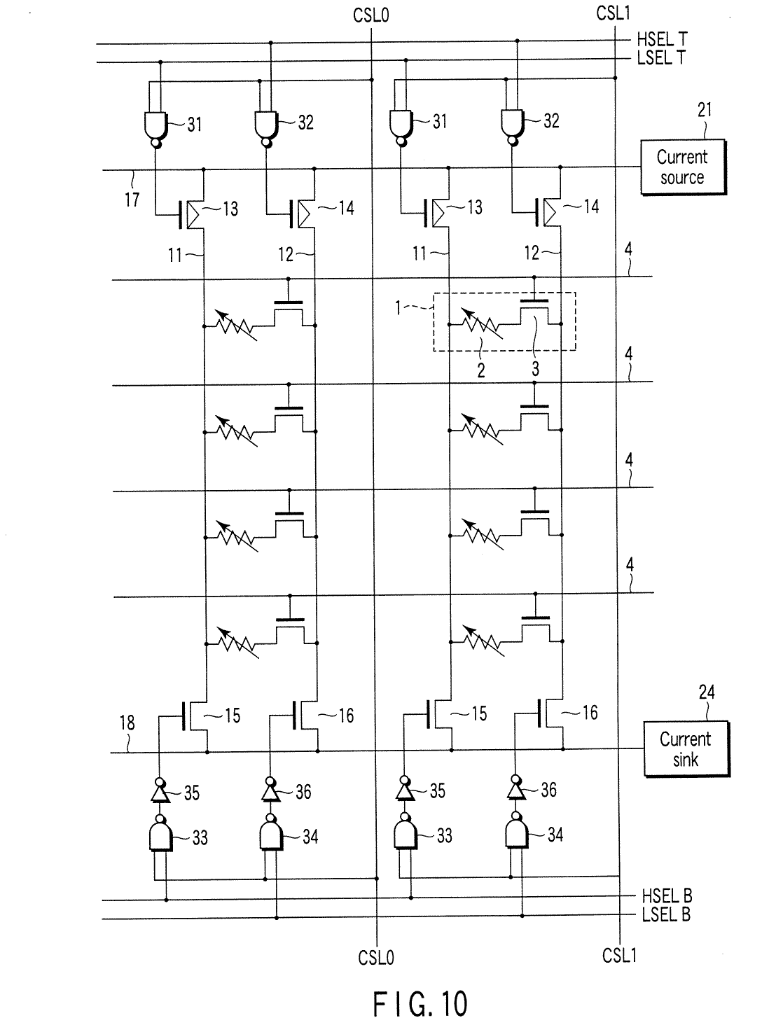

FIG. 10 shows a circuit configuration of a magnetic memory device according to the fourth embodiment of the invention. As shown in FIG. 10, a NAND circuit 31 is provided for each transistor 13. An output of the NAND circuit 31 is supplied to the gate electrode of the associated transistor 13.

A NAND circuit 32 is provided for each transistor 14. An output of the NAND circuit 32 is supplied to the gate electrode of the associated transistor 14.

A NAND circuit 33 and an inverter circuit 35, which are connected in series, are provided for each transistor 15. An output of the inverter circuit 35 is supplied to the gate electrode of the associated transistor 15.

A NAND circuit 34 and an inverter circuit 36, which are connected in series, are provided for each transistor 16. An output of the inverter circuit 36 is supplied to the gate electrode of the associated transistor 16.

The NAND circuits 31 to 34 and inverter circuits 35 and 36 constitute parts of the control circuit 6 shown in FIG. 4.

A column select signal CSL0 for selecting a first column (left column in FIG. 10) is supplied to a first input terminal of each of the NAND circuits 31 to 34 included in the first column. A column select signal CSL1 for selecting a second column (right column in FIG. 10) is supplied to a first input terminal of each of the NAND circuits 31 to 34 included in the second column.

A data determination signal LSELT is supplied to a second input terminal of the NAND circuit 31 in each column. A data determination signal HSELT is supplied to a second input terminal of the NAND circuit 32 in each column. A data determination signal HSELB is supplied to a second input terminal of the NAND circuit 33 in each column. A data determination signal LSELB is supplied to a second input terminal of the NAND circuit 34 in each column.

Remaining parts of the present embodiment are the same as the first embodiment (FIG. 2).

At a write time, in order to select the memory cell 1 in the first column, the column select signal CSL0 is set at high level. In order to select the memory cell 1 in the second column, the column select signal CSL1 is set at high level. In order to write first data (e.g. “0” data), both data determination signals LSELT and LSELB are set at high level with one of the column select signal CSL0 and CSL1 set at high level. This control turns on the transistors 13 and 16 in the column including the selected memory cell 1. In addition, the select transistor 3 of the selected memory cell 1 is turned on and the current source circuit 21 is activated, and thereby the first data is written in the selected memory cell 1.

In order to write second data (e.g. “1” data), both data determination signals HSELT and HSELB are set at high level with one of the column select signal CSL0 and CSL1 set at high level. This control turns on the transistors 14 and 15 in the column including the selected memory cell 1. In addition, the select transistor 3 of the selected memory cell 1 is turned on and the current source circuit 21 is activated.

The structure for controlling the transistors 13 to 16 has been described in connection with only the first embodiment. The same control can be applied to the transistors 13 to 16 of the second and third embodiments.

FIG. 10 depicts only two columns for the purpose of simplicity. A structure including three or more columns can be realized by providing the same number of column select lines, only one of which is set at high level, as the number of columns. The respective columns share the current source circuit 21 and current sink circuit 24.

The magnetic memory device of the fourth embodiment of the invention can provide the same advantageous effect as the first embodiment.

### Fifth Embodiment

A fifth embodiment of the invention relates to a structure (control circuit 6) for controlling on/off of the transistors 13 to 16.

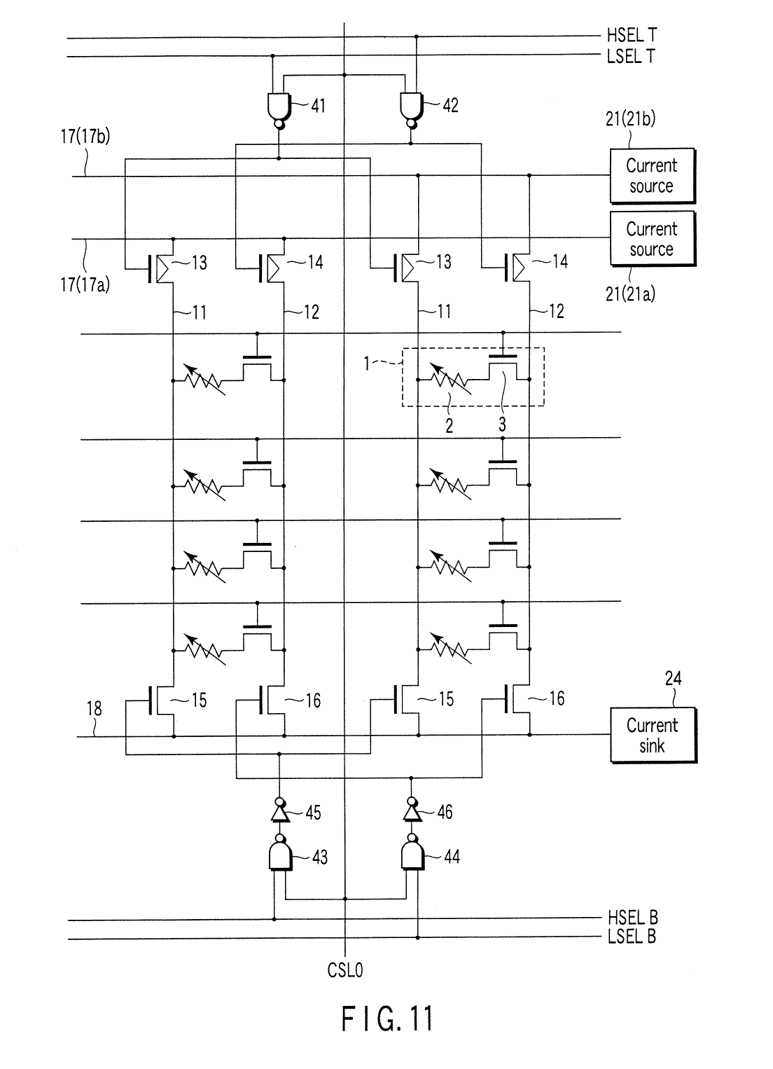

FIG. 11 shows a circuit configuration of a magnetic memory device according to the fifth embodiment of the invention. As shown in FIG. 11, the other end of each of the transistors 13 and 14 in the first column (left column in FIG. 11) are connected to a current source circuit 21 (21a) via a common line 17 (17a). The other end of each of the transistors 13 and 14 in the second column (right column in FIG. 11) are connected to a current source circuit 21 (21b) via a common line 17 (17b).

One NAND circuit 41 is provided for the transistors 13 of the two columns. An output of the NAND circuit 41 is supplied to the gate electrode of each transistor 13.

One NAND circuit 42 is provided for the transistors 14 of the two columns. An output of the NAND circuit 42 is supplied to the gate electrode of each transistor 14.

A NAND circuit 43 and an inverter circuit 45, which are connected in series, are provided for the transistors 15 of the two columns. An output of the inverter circuit 45 is supplied to the gate electrode of each transistor 15.

A NAND circuit 44 and an inverter circuit 46, which are connected in series, are provided for the transistors 16 of the two columns. An output of the inverter circuit 46 is supplied to the gate electrode of each transistor 16.

The NAND circuits 41 to 44 and inverter circuits 45 and 46 constitute parts of the control circuit 6 shown in FIG. 4.

A column select signal CSL0 for selecting the first column and second column is supplied to the first input terminal of each of the NAND circuits 41 to 44. A data determination signal LSELT is supplied to the second input terminal of the NAND circuit 41. A data determination signal HSELT is supplied to the second input terminal of the NAND circuit 42. A data determination signal HSELB is supplied to the second input terminal of the NAND circuit 43. A data determination signal LSELB is supplied to the second input terminal of the NAND circuit 44.

Remaining parts of the present embodiment are the same as the first embodiment (FIG. 2).

In order to write first data (e.g. “0” data) in the memory cell 1 in the first column or second column, both data determination signals LSELT and LSELB are set at high level with the column select signal CSL0 set at high level. This control turns on the transistors 13 and 16 in the first and second columns. The select transistor 3 of the selected memory cell 1 is then turned on. In this state, when the selected memory cell 1 is included in the first column, the current source circuit 21a, which is connected to the first column, is activated. When the selected memory cell 1 is included in the second column, the current source circuit 21b, which is connected to the second column, is activated.

In order to write second data (e.g. “1” data), both data determination signals HSELT and HSELB are set at high level with the column select signal CSL0 set at high level. This control turns on the transistors 14 and 15 in the first and second columns. The select transistor 3 of the selected memory cell 1 is then turned on. In this state, when the selected memory cell 1 is included in the first column, the current source circuit 21a, which is connected to the first column, is activated. When the selected memory cell 1 is included in the second column, the current source circuit 21b, which is connected to the second column, is activated.

The structure for controlling the transistors 13 to 16 has been described in connection with only the first embodiment. The same control can be applied to the transistors 13 to 16 of the second and third embodiments.

FIG. 11 depicts only two columns for the purpose of simplicity. A structure including 2 n (n being natural number) columns, e.g. four columns or six columns, can be realized by providing a plurality of the 2-column units shown in FIG. 11, and providing a plurality of column select signals, only one of which is set at high level, for the respective 2-column units. One of the two columns of each 2-column unit share the current source circuit 21a, and the other of the two columns of each 2-column unit share the current source circuit 21b. The respective columns share the current sink circuit 24.

The magnetic memory device of the fifth embodiment of the invention can provide the same advantageous effect as the first embodiment.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A magnetic memory device comprising:
a first magnetoresistance element having a first end and a second end, first data being written into the first magnetoresistance element by an electric current flowing from the first end to the second end, and second data being written into the first magnetoresistance element by an electric current flowing from the second end to the first end;
a first p-type MOSFET having one end connected to the first end;
a second p-type MOSFET having one end connected to the second end;
a first n-type MOSFET having one end connected to the first end;
a second n-type MOSFET having one end connected to the second end;
a first current source circuit connected to another end of the first p-type MOSFET and another end of the second p-type MOSFET and supplying an electric current; and
a first current sink circuit connected to another end of the first n-type MOSFET and another end of the second n-type MOSFET and drawing an electric current.

2. The device according to claim 1, wherein
the first p-type MOSFET and the second n-type MOSFET are on, and the second p-type MOSFET and the first n-type MOSFET are off when the first data is written into the first magnetoresistance element, and
the second p-type MOSFET and the first n-type MOSFET are on, and the first p-type MOSFET and the second n-type MOSFET are off when the second data is written into the first magnetoresistance element.

3. The device according to claim 2, wherein the first and second n-type MOSFETs stay on during a standby state.

4. The device according to claim 2, wherein the current source circuit is a constant voltage source.

5. The device according to claim 1, further comprising:
a second magnetoresistance element having a third end and a fourth end, data being written into the second magnetoresistance element by an electric current flowing from the third end to the fourth end or an electric current flowing from the fourth end to the third end;
a third p-type MOSFET connected between the third end and the first current source circuit;
a fourth p-type MOSFET connected between the fourth end and the first current source circuit;
a third n-type MOSFET having one end connected to the third end;
a fourth n-type MOSFET having one end connected to the fourth end; and
a second current sink circuit connected to another end of the third n-type MOSFET and another end of the fourth n-type MOSFET and drawing an electric current.

6. The device according to claim 1, further comprising:
a second magnetoresistance element having a third end and a fourth end, data being written into the second magnetoresistance element by an electric current flowing from the third end to the fourth end or an electric current flowing from the fourth end to the third end;
a third n-type MOSFET connected between the third end and the first current sink circuit;
a fourth n-type MOSFET connected between the fourth end and the first current sink circuit;
a third p-type MOSFET having one end connected to the third end;
a fourth p-type MOSFET having one end connected to the fourth end; and
a second current source circuit connected to anther end of the third p-type MOSFET and another end of the fourth p-type MOSFET and drawing an electric current.

7. The device according to claim 1, further comprising:
a first control circuit outputting a first control signal when supplied with a first signal and a first select signal, the first p-type MOSFET being turned on when supplied with the first control signal;
a second control circuit outputting a second control signal when supplied with a second signal and the first select signal, the second p-type MOSFET being turned on when supplied with the second control signal;
a third control circuit outputting a third control signal when supplied with a third signal and the first select signal, the first n-type MOSFET being turned on when supplied with the third control signal; and
a fourth control circuit outputting a fourth control signal when supplied with a fourth signal and the first select signal, the second n-type MOSFET being turned on when supplied with the fourth control signal.

8. The device according to claim 7, further comprising:
a second magnetoresistance element having a third end and a fourth end, data being written into the second magnetoresistance element by an electric current flowing from the third end to the fourth end or an electric current flowing from the fourth end to the third end;
a third p-type MOSFET connected between the third end and the first current source circuit;
a fourth p-type MOSFET connected between the fourth end and the first current source circuit;
a third n-type MOSFET connected between the third end and the first current sink circuit;
a fourth n-type MOSFET connected between the fourth end and the first current sink circuit;
a fifth control circuit outputting a fifth control signal when supplied with the first signal and a second select signal, the third p-type MOSFET being turned on when supplied with the fifth control signal;
a sixth control circuit outputting a sixth control signal when supplied with the second signal and the second select signal, the fourth p-type MOSFET being turned on when supplied with the sixth control signal;
a seventh control circuit outputting a seventh control signal when supplied with the third signal and the second select signal, the third n-type MOSFET being turned on when supplied with the seventh control signal; and
an eighth control circuit outputting an eighth control signal when supplied with the fourth signal and the second select signal, the fourth n-type MOSFET being turned on when supplied with the eighth control signal.

9. The device according to claim 7, further comprising:
a second magnetoresistance element having a third end and a fourth end, data being written into the second magnetoresistance element by an electric current flowing from the third end to the fourth end or an electric current flowing from the fourth end to the third end;
a second current source circuit supplying an electric current, one of the first and second current source circuits being inoperative while the other being operating;
a third p-type MOSFET connected between the third end and the second current source circuit, the third p-type MOSFET being turned on when supplied with the first control signal;
a fourth p-type MOSFET connected between the fourth end and the second current source circuit, the fourth p-type MOSFET being turned on when supplied with the second control signal;
a third n-type MOSFET connected between the third end and the first current sink circuit, the third n-type MOSFET being turned on when supplied with the third control signal; and
a fourth n-type MOSFET connected between the fourth end and the first current sink circuit, the fourth n-type MOSFET being turned on when supplied with the fourth control signal.

10. A method of writing data in a magnetic memory device, the device comprising:
a first magnetoresistance element having a first end and a second end, first data being written into the first magnetoresistance element by an electric current flowing from the first end to the second end, and second data being written into the first magnetoresistance element by an electric current flowing from the second end to the first end;
a first p-type MOSFET having one end connected to the first end;
a second p-type MOSFET having one end connected to the second end;
a first n-type MOSFET having one end connected to the first end;
a second n-type MOSFET having one end connected to the second end;
a first current source circuit connected to another end of the first p-type MOSFET and another end of the second p-type MOSFET and supplying an electric current; and
a first current sink circuit connected to another end of the first n-type MOSFET and another end of the second n-type MOSFET and drawing an electric current, and
the method comprising:
turning on the first p-type MOSFET and the second n-type MOSFET, turning off the second p-type MOSFET and the first n-type MOSFET and activating the first current source circuit for writing the first data into the first magnetoresistance element; and
turning on the second p-type MOSFET and the first n-type MOSFET, turning off the first p-type MOSFET and the second n-type MOSFET and activating the first current source circuit for writing the second data into the first magnetoresistance element.

11. The method according to claim 10, further comprising:
keeping the first and second n-type MOSFETs on during a standby state.

12. The method according to claim 10, wherein the device further comprises:
a second magnetoresistance element having a third end and a fourth end, first data being written into the second magnetoresistance element by an electric current flowing from the third end to the fourth end, and second data being written into the second magnetoresistance element by an electric current flowing from the fourth end to the third end;
a third p-type MOSFET connected between the third end and the first current source circuit;
a fourth p-type MOSFET connected between the fourth end and the first current source circuit;
a third n-type MOSFET having one end connected to the third end;
a fourth n-type MOSFET having one end connected to the fourth end; and
a second current sink circuit connected to another end of the third n-type MOSFET and another end of the fourth n-type MOSFET and drawing an electric current, and
the method further comprises:
turning on the third p-type MOSFET and the fourth n-type MOSFET, turning off the fourth p-type MOSFET and the third n-type MOSFET and activating the first current source circuit for writing the first data into the second magnetoresistance element; and
turning on the fourth p-type MOSFET and the third n-type MOSFET, turning off the third p-type MOSFET and the fourth n-type MOSFET and activating the first current source circuit for writing the second data into the second magnetoresistance element.

13. The method according to claim 10, wherein
the device further comprises:
a second magnetoresistance element having a third end and a fourth end, first data being written into the second magnetoresistance element by an electric current flowing from the third end to the fourth end, and second data being written into the second magnetoresistance element by an electric current flowing from the fourth end to the third end;
a third n-type MOSFET connected between the third end and the first current sink circuit;
a fourth n-type MOSFET connected between the fourth end and the first current sink circuit;
a third p-type MOSFET having one end connected to the third end;
a fourth p-type MOSFET having one end connected to the fourth end; and
a second current source circuit connected to another end of the third p-type MOSFET and another end of the fourth p-type MOSFET and drawing an electric current, and
the method further comprises:
turning on the third p-type MOSFET and the fourth n-type MOSFET, turning off the fourth p-type MOSFET and the third n-type MOSFET and activating the second current source circuit for writing the first data into the second magnetoresistance element; and
turning on the fourth p-type MOSFET and the third n-type MOSFET, turning off the third p-type MOSFET and the fourth n-type MOSFET and activating the second current source circuit for writing the second data into the second magnetoresistance element.

14. The method according to claim 10, further comprising:
providing a first control circuit with a first signal and a first select signal to cause the first control circuit to output a first control signal, the first p-type MOSFET being turned on when supplied with the first control signal;
providing a second control circuit with a second signal and the first select signal to cause the second control circuit to output a second control signal, the second p-type MOSFET being turned on when supplied with the second control signal;
providing a third control circuit with a third signal and the first select signal to cause the third control circuit to output a third control signal, the first n-type MOSFET being turned on when supplied with the third control signal; and
providing a fourth control circuit with a fourth signal and the first select signal to cause the fourth control circuit to output a fourth control signal, the second n-type MOSFET being turned on when supplied with the fourth control signal.

15. The method according to claim 10, wherein
the device further comprises:
a second magnetoresistance element having a third end and a fourth end, first data being written into the second magnetoresistance element by an electric current flowing from the third end to the fourth end, and second data being written into the second magnetoresistance element by an electric current flowing from the fourth end to the third end;
a third p-type MOSFET connected between the third end and the first current source circuit;
a fourth p-type MOSFET connected between the fourth end and the first current source circuit;
a third n-type MOSFET connected between the third end and the first current sink circuit; and
a fourth n-type MOSFET connected between the fourth end and the first current sink circuit, and
the method further comprises:
providing a fifth control circuit with the first signal and a second select signal to cause the fifth control circuit to output a fifth control signal, the third p-type MOSFET being turned on when supplied with the fifth control signal;
providing a sixth control circuit with the second signal and the second select signal to cause the sixth control circuit to output a sixth control signal, the fourth p-type MOSFET being turned on when supplied with the sixth control signal;
providing a seventh control circuit with the third signal and the second select signal to cause the seventh control circuit to output a seventh control signal, the third n-type MOSFET being turned on when supplied with the seventh control signal; and
providing an eighth control circuit with the fourth signal and the second select signal to cause the eighth control circuit to output an eighth control signal, the fourth n-type MOSFET being turned on when supplied with the eighth control signal.

16. The method according to claim 14, wherein
the device further comprises:
a second magnetoresistance element having a third end and a fourth end, data being written into the second magnetoresistance element by an electric current flowing from the third end to the fourth end or an electric current flowing from the fourth end to the third end;
a second current source circuit supplying an electric current;
a third p-type MOSFET connected between the third end and the second current source circuit, the third p-type MOSFET being turned on when supplied with the first control signal;
a fourth p-type MOSFET connected between the fourth end and the second current source circuit, the fourth p-type MOSFET being turned on when supplied with the second control signal;
a third n-type MOSFET connected between the third end and the first current sink circuit, the third n-type MOSFET being turned on when supplied with the third control signal; and
a fourth n-type MOSFET connected between the fourth end and the first current sink circuit, the fourth n-type MOSFET being turned on when supplied with the fourth control signal, and
the method further comprises:
activating the first current source circuit and inactivating the second current source circuit for writing data into the first magnetoresistance element; and
activating the second current source circuit and inactivating the first current source circuit for writing data into the second magnetoresistance element.
